(19) United States
(12) Patent Application Publication
(10) Pub. No.: US 2024/0071969 A1
(43) Pub. Date: Feb. 29, 2024

(54) SEMICONDUCTOR DIE STACKS AND ASSOCIATED SYSTEMS AND METHODS

(71) Applicant: Micron Technology, Inc., Boise, ID (US)

(72) Inventors: Kyle K. Kirby, Eagle, ID (US); Bret K. Street, Meridian, ID (US); Bang-Ning Hsu, Taichung (TW)

(21) Appl. No.: 18/220,734

(22) Filed: Jul. 11, 2023

Related U.S. Application Data
(60) Provisional application No. 63/401,636, filed on Aug. 27, 2022.

(51) Int. Cl. H01L 23/00; H01L 25/065

(52) U.S. Cl. CPC H01L 24/08; H01L 24/16; H01L 24/48; H01L 24/80; H01L 25/0657; H01L 2224/08146; H01L 2224/16145; H01L 2224/16227; H01L 2224/48229; H01L 2224/80895; H01L 2225/06513; H01L 2225/06517; H01L 2225/06541; H01L 2924/1431; H01L 2924/1436; H01L 2924/1437; H01L 2924/1438

(57) ABSTRACT

Semiconductor devices and semiconductor device assemblies, and related systems and methods, are disclosed herein. In some embodiments, the semiconductor device includes a support substrate, a first die package carried by the support substrate, and a second die package carried by the first die package. Each of the first and second die packages can include a first die, a second die hybrid bonded a surface of the first die, and a third die hybrid bonded to a surface of the second die. The first die is coupled to the third die via an interconnect portion of the second die. Further, the third die can include an array of active cells for each of the packages, the second die can include complementary-metal-oxide-semiconductor (CMOS) circuitry accessing the active cells, and the first die can include backend of line (BEOL) circuitry associated with the active cells and CMOS circuitry.

### CROSS-REFERENCE TO RELATED APPLICATION(S)

The present application claims priority to U.S. Provisional Patent Application No. 63/401,636, filed Aug. 27, 2022, the disclosure of which is incorporated herein by reference in its entirety.

### TECHNICAL FIELD

The present technology is generally related to systems and methods for reducing cracks in a solder mask. In particular, the present technology relates to opening patterns in solder masks that release stress and related systems and methods.

### BACKGROUND

Microelectronic devices, such as memory devices, microprocessors, and other electronics, typically include one or more semiconductor dies mounted to a substrate and encased in a protective covering. The semiconductor dies include functional features, such as memory cells, processor circuits, imager devices, interconnecting circuitry, etc. To meet continual demands on decreasing size, individual semiconductor dies and/or active components are typically manufactured in bulk and then stacked on a support substrate (e.g., a printed circuit board (PCB) or other suitable substrates). The stacked dies can then be coupled to the support substrate (sometimes also referred to as a package substrate) through bond wires in shingle-stacked dies (e.g., dies stacked with an offset for each die) and/or through substrate vias (TSVs) between the dies and the support substrate.

### BRIEF DESCRIPTION OF THE DRAWINGS

FIG. 1 is a partially schematic cross-sectional view of a typical semiconductor device.

FIG. 2 is a partially schematic cross-sectional view of a semiconductor die package configured in accordance with some embodiments of the present technology.

FIG. 3 is a partially schematic cross-sectional view of a semiconductor device configured in accordance with further embodiments of the present technology.

FIG. 4 is a partially schematic cross-sectional view of a semiconductor die package configured in accordance with further embodiments of the present technology.

FIGS. 5A and 5B are partially schematic views of a semiconductor device configured in accordance with some embodiments of the present technology.

FIG. 6 is a flow diagram of a process for manufacturing a semiconductor die package in accordance with some embodiments of the present technology.

FIG. 7 illustrates a semiconductor die package after various steps of the manufacturing process of FIG. 6 in accordance with embodiments of the present technology.

FIG. 8 is a partially schematic cross-sectional view of a semiconductor device configured in accordance with further embodiments of the present technology.

FIG. 9 is a schematic view of a system that includes a semiconductor die assembly configured in accordance with embodiments of the present technology.

The drawings have not necessarily been drawn to scale. Further, it will be understood that several of the drawings have been drawn schematically and/or partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

Specific details of several embodiments of semiconductor die packages, stacked semiconductor assemblies, and associated systems and methods are described below. The term “semiconductor device or die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Further, the term “semiconductor device or die” can refer to a finished device or to an assembly or other structure at various stages of processing before becoming a finished functional device. Depending upon the context in which it is used, the term “substrate” can refer to a wafer-level substrate or to a singulated, die-level substrate. Also, a substrate may include a semiconductor wafer, a package support substrate, an interposer, a semiconductor device or die, or the like. A person having ordinary skill in the relevant art will recognize that suitable steps of the methods described herein can be performed at the wafer level or at the die level.

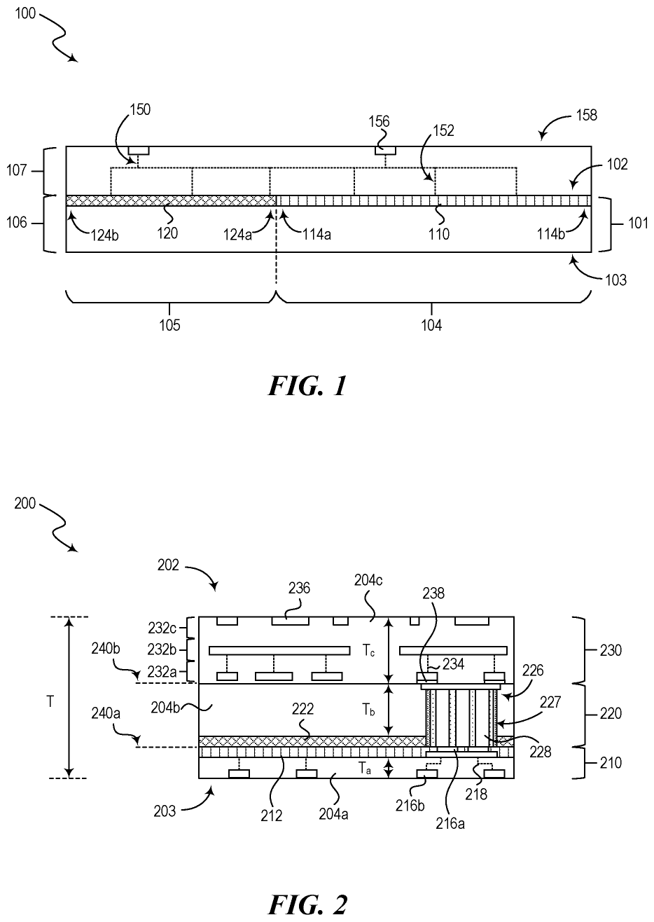

Further, unless the context indicates otherwise, structures disclosed herein can be formed using conventional semiconductor-manufacturing techniques. Materials can be deposited, for example, using chemical vapor deposition (CVD), physical vapor deposition (PVD), atomic layer deposition (ALD), spin coating, plating, and/or other suitable techniques. Similarly, materials can be removed, for example, using plasma etching, wet etching, chemical-mechanical planarization, or other suitable techniques. Some of the techniques may be combined with photolithography processes. A person skilled in the relevant art will also understand that the technology may have additional embodiments, and that the technology may be practiced without several of the details of the embodiments described herein with reference to FIGS. 1-9.

Certain semiconductor devices, (e.g., a memory device), include an area with an array of active cells (which may also be referred to as an array, a memory array, an array region, an array portion, or the like) and another area with peripheral circuitry (which may also be referred to as a periphery, a peripheral region, a peripheral portion, or the like) and back end of line (BEOL) component. Purely by way of example, in a memory device, the array of active cells can include various types of memory cells, such as dynamic random-access memory (DRAM) cells, phase change memory (PCM) cells, flash memory cells (e.g., NAND cells, NOR cells, and the like), among others. The peripheral circuitry can be configured to perform various functions for the semiconductor device, including accessing the active cells of the array. In some cases, the peripheral region may be referred to as a CMOS region (CMOS, CMOS portion, and/or CMOS area) in view of complementary-metal-oxide-semiconductor (CMOS) transistors included in the peripheral circuitry. Additionally, or alternatively, the peripheral region may be referred to as a logic region owing to the nature of digital logic functions that the peripheral circuitry performs. As such, the memory device may be regarded to have an array region and a CMOS region (or a peripheral/logic region), among others. The BEOL component can include one or more metallization layers that form electrical connections between the active cells and the peripheral circuitry, components of the active cells, components of the peripheral circuitry (e.g., transistors, capacitors, resistors, and the like). Additionally, or alternatively, the BEOL component can couple the active cells and/or the peripheral circuitry to external components (e.g., other semiconductor dies, a support substrate, and the like).

Semiconductor die packages, semiconductor die assemblies, and associated systems and methods are disclosed herein. A semiconductor die package (also sometimes referred to herein as “packages” and/or “composite dies”) can include a first, second, and third semiconductor dies conjoined in the package. More specifically, each of the first, second, and third semiconductor dies can include a semiconductor substrate (e.g., first, second, and third semiconductor substrates, respectively). The first semiconductor substrate can be directly bonded to the second semiconductor substrate at a first interface, and the second semiconductor substrate can be directly bonded to the third semiconductor substrate at a second interface. As a result, the conjoined dies can form a unitary package.

The first semiconductor die can a plurality of metallization layers that form back end of line (BEOL) circuitry within the first semiconductor substrate. The first semiconductor substrate can have an inner surface and an outer surface opposite the inner surface. The plurality of metallization layers can include conductive components at the inner surface (e.g., at the first interface), and can form electrical routes between the inner surface and the outer surface.

Similarly, the second semiconductor die can include complementary metal-oxide-semiconductor (CMOS) circuitry (and/or other peripheral circuitry) formed on a front surface of the second semiconductor substrate. The back surface of the second semiconductor substrate can include one or more conductive components that are directly bonded (e.g., through metal-metal bonds) to the conductive components at the inner surface of the first semiconductor substrate. Further, the second semiconductor die can also include an interconnect section electrically coupling the conductive components at the back surface to one or more conductive components at the front surface.

The third semiconductor die can include an array of active cells formed on a front side of the third semiconductor substrate along with one or more conductive components. The conductive components on the front side of the third semiconductor substrate can be directly bonded (e.g., through metal-metal bonds) to the conductive components at the front surface of the second semiconductor substrate to provide the CMOS circuitry with access to the active cells and/or to electrically couple the active cells to the BEOL circuitry through the interconnect section.

The composite construction of the package can allow each of the first, second, and third semiconductor dies to be manufactured in processes specific to the components thereon and/or with dimensions specific to the components thereon. For example, each of the first, second, and third semiconductor substrates can have a thickness specific to the components on the first, second, and third semiconductor dies to (e.g., independent from the thicknesses of the other dies). In a specific, non-limiting example, the first semiconductor substrate has a first thickness, the second semiconductor substrate has a second thickness different than the first thickness, and the third semiconductor substrate has a third thickness different than the first thickness and the second thickness.

In some embodiments, each of the first, second, and third semiconductor dies has a generally equal longitudinal footprint. In such embodiments, the outer surface of the first semiconductor substrate can include one or more first bond pads, and the back side of the third semiconductor substrate can include one or more second bond pads. The first and second bond pads can be individually vertically aligned. The alignment can allow multiple packages to be stacked and interconnected on a package support substrate (sometimes referred to herein as a “support substrate” and/or a “package substrate”). In some embodiments, the first die has a larger longitudinal footprint, thereby creating a porch for one or more bond pads to facilitate a bond wire connection to the package. In such embodiments, the second semiconductor substrate and the third semiconductor substrate can have a combined thickness that is greater than a height to which bond wires will be rise when attached to the bond pads rise one the first semiconductor substrate. The bond wires can coupled the package to one or more substrate bond pads on a support substrate.

In some embodiments, the package includes one or more additional dies conjoined to the first die opposite the second and third dies (e.g., conjoined to the outer surface). For example, the plurality of metallization layers can include conductive components at the outer surface of the first semiconductor substrate, and a fourth semiconductor die can be conjoined to the outer surface. Similar to the second semiconductor die, the fourth semiconductor substrate can include CMOS circuitry formed in a fourth semiconductor substrate and/or an interconnect section electrically coupled to the conductive components at the outer surface of the first semiconductor die. Further, the package can include a fifth semiconductor die conjoined to the fourth semiconductor die. Similar to the third semiconductor die, the fifth semiconductor die can include an array of additional active cells formed a fifth semiconductor substrate. Further, a front side of the fifth semiconductor substrate can include conductive components electrically coupled to the interconnect section of the fourth die and/or the CMOS circuitry of the fourth die.

In some embodiments, a semiconductor die assembly can include one or more packages of the type discussed above carried by, and electrically coupled to, a package support surface. For example, the semiconductor die assembly can include a first die package carried by the support substrate and a second die package carried by the first die package. The first die package can include a first die having an inner surface and an outer surface, a second die having a back surface hybrid bonded to the inner surface of the first die and a front surface opposite the back surface, and a third die having a front side hybrid bonded to the front surface of the second die and a back side opposite the front side. Similar to the discussion above, the first die can be coupled to the third die via an interconnect portion of the second die. Similarly, the second die package can incldue a fourth die having an inner surface and an outer surface, a fifth die having a back surface hybrid bonded to the inner surface of the fourth die and a front surface opposite the back surface, and a sixth die having a front side hybrid bonded to the front surface of the fifth die and a back side opposite the front side.

The first die package can be electrically coupled to at least one first substrate bond pad on the support substrate while the second die package can electrically coupled to at least one second substrate bond pad on the support substrate. In some embodiments, the first die has an exposed portion extending beyond the second and third dies (e.g., a porch) that includes a bond pad. In such embodiments, the semiconductor die assembly can further include a bond wire electrically coupling the bond pad to the at least one first substrate bond pad. Similarly, the fourth die can have an exposed portion extending beyond a footprint of the fifth die and the sixth die that includes a bond pad. The bond pad on the fourth die can be electrically coupled to the at least one second substrate bond pad through another bond wire.

In some embodiments, the first and second packages are electrically coupled by one or more conductive structures (e.g., solder balls) therebetween. Similarly, the first package can be electrically coupled to the support substrate by one or more conductive structures therebetween. The conductive structures, along with the conductive interconnects, routing lines, and the like in each of the first and second packages can establish the electrically connections in the semiconductor die assembly.

As used herein, the terms “front,” “back,” “vertical,” “lateral,” “down,” “up,” “upper,” and “lower” can refer to relative directions or positions of features in the semiconductor device assemblies in view of the orientation shown in the Figures. For example, “upper” or “uppermost” can refer to a feature positioned closer to the top of a page than another feature. These terms, however, should be construed broadly to include semiconductor devices having other orientations. Unless stated otherwise, terms such as “first” and “second” are used to arbitrarily distinguish between the elements such terms describe. Thus, these terms are not necessarily intended to indicate temporal or other prioritization of such elements. Moreover, although in the example embodiments herein, semiconductor die stacks with two dies (e.g., semiconductor die pairs) are used to illustrate clearly the overall features and the principles of the present technology, the present technology is not limited thereto. For example, in some embodiments, a semiconductor die stack could include a single larger die carrying two or more smaller ones. Additionally, or alternatively, one or more smaller ones carried by the single larger die may include a stack of dies.

FIG. 1 is a partially schematic cross-sectional view of a typical semiconductor device 100 having a substrate 101 with front side 102 and a backside 103. The semiconductor device 100 includes an array region 104 and a peripheral region 105, as well as a front end of line (FEOL) portion 106 and a back end of line (BEOL) portion 107. The FEOL portion 106 can include an array of active cells 110 and CMOS circuitry 120 (and/or various other peripheral or logic circuitry) formed at the front side 102 of the substrate 101. The active cells 110 can include memory cells (e.g., DRAM cells, 3D NAND cells, NOR cell, and the like), processor cells, imager cells, and the like. The CMOS circuitry 120 can include transistors, resistors, capacitors, command and/or address decoders, column decoders, row decoders, sense amplifiers, and the like, which can be configured to access the array of active cells 110.

The FEOL portion 106 can be produced by two or more first phases of manufacturing. For example, a first manufacturing phase can form the active cells 110 through various suitable processes specific to the formation of the active cells 110, while a second manufacturing phase can form the CMOS circuitry 120 through various suitable processes specific to the formation of the CMOS circuitry 120. The first and second manufacturing processes associated with forming the active cells 110 and the CMOS circuitry 120 typically involve conflicting processing steps and temperatures.

Once the FEOL portion 106 is complete, the BEOL portion 107 is formed on the front side 102 of the semiconductor substrate 101. The BEOL portion 107 can include one or more metallization layers that form conductive routing lines 152 (shown schematically in FIG. 1), contacts, insulation layers (e.g., dielectric layers), interconnects 154, and/or bond sites 156. The conductive routing lines 152 can electrically couple the array region 104 and the peripheral region 105 (e.g., coupling an active cell to a CMOS transistor), various components of the array region 104 to each other, various components of the peripheral region 105 to each other, and/or any of the components in the FEOL portion 106 to one or more of the interconnects 150. The interconnects 150 can couple the components in the FEOL portion 106 to the bond sites 156 on an outer surface 158 of the BEOL portion 107 (e.g., thereby forming a signal route line from the outer surface 158 to one of the active cells 110). Similar to the discussion above, the BEOL portion 107 is formed through various manufacturing processes specific to the structures of the BEOL portion, including with materials and temperatures diverse from the processes associated with the active cells 110 and/or the CMOS circuitry 120.

The cross-sectional view of the semiconductor device 100 in FIG. 1 also illustrates an issue related to positioning the array region 104 and the peripheral region 105 on a coplanar surface (e.g., the front side 102 of the semiconductor device 100). For example, signals propagating, through the BEOL portion 107, between the active cells 110 and the CMOS circuitry 120 (e.g., voltage and/or current traveling different distances between the array of active cells 110 and the CMOS circuitry 120) may exhibit different delays for the semiconductor device 100 to handle. In this regard, the array region 104 can include near cells 114a (e.g., one or more active cells located proximate to the peripheral region 105) and far cells 114b (e.g., one or more active cells located relatively far from the peripheral region 105). Similarly, the peripheral region 105 can include near CMOS-components 124a (e.g., row decoders located proximate to the array region 104) and far CMOS-components 124b (e.g., row decoders located relatively far from the array region 104). The worst-case delay in the signal propagation may be between the far cells 114b and the far CMOS-components 124b while the best-case delay may be between the near cells 114a and the near CMOS-components 124a. Various schemes may be devised to reduce a range in the signal propagation delays, such as coupling the near CMOS-components 124a with the far cells 114b and the far CMOS-components 124b with the near cells 114a, partitioning the array region 104 to two or more sub-regions and/or partitioning the peripheral region 105 to two or more sub-regions such that the sub-regions of the array region 104 and the peripheral region 105 may be interspersed, among others.

Additionally, or alternatively, signal route lines through the BEOL portion 107 can be configured to account for varying signal delays between components the array region 104 and the peripheral region 105. For example, signal routes (sometimes called traces) between components in the near cells 114a and the near CMOS-components 124a can have a serpentine shape that effectively increases the travel length for the signals. These trace matching features can help maintain equal timing of signals in the semiconductor device 100.

FIG. 2 is a partially schematic cross-sectional view of a semiconductor die package 200 configured in accordance with some embodiments of the present technology. The semiconductor die package 200 (“package 200”) includes a third semiconductor die 210, a second semiconductor die 220 bonded to the third semiconductor die 210, and a first semiconductor die 230 bonded to the second semiconductor die 220. More specifically, in the illustrated embodiment, third semiconductor die 210 (sometimes also referred to herein as an “array die” and/or an “array portion”) includes a front side that is conjoined to a front surface of the second semiconductor die 220 (sometimes also referred to herein as a “CMOS die” and/or a “CMOS portion”). For example, the third semiconductor die 210 can include a base substrate 204a and an array of active cells 212 formed on the front side while the second semiconductor die 220 includes a base substrate 204b and CMOS circuitry 222 (and/or other peripheral circuitry) formed on the front surface. In some embodiments, conjoining the third and second semiconductor dies 210, 220 includes forming a hybrid bond at a first interface 240a therebetween. That is, the base substrates 204a, 204b and one or more conductive components from the active cells 212 and the CMOS circuitry 222 can be directly bonded at the first interface 240a. The direct bond can allow some components of the CMOS circuitry 222 to access components of the active cells 212 directly, with reduced signal travel paths and/or general equidistant travels paths, without requiring numerous trace matching features. Additionally, or alternatively, the hybrid bond can allow the third and second semiconductor dies 210, 220 to be treated as a single die during additional manufacturing processes.

The second semiconductor die 220 can also include an interconnect portion 226 extending from the front surface to a back surface opposite the front surface. The interconnect portion 226 includes one or more conductive interconnects 228 (three illustrated in FIG. 2) that are surrounded by an insulating material 227 (e.g., a dielectric liner), thereby providing a signal route between the front and back surfaces. Further, the conductive interconnects 228 can be directly bonded to one or more first bond pads 216a (two shown) at the font side of the third semiconductor die 210.

As further illustrated in FIG. 2, the first semiconductor die 230 (sometimes also referred to herein as a “BEOL die” and/or a “BEOL portion”) includes a base substrate 204c having an inner surface (sometimes also referred to herein as a “die-stacking surface”) that is conjoined to the back surface of the second semiconductor die 220. Similar to the conjunction at the first interface 240a, the second and third semiconductor dies 220, 230 can be hybrid bonded at a second interface 240b. For example, the base substrates 204b, 204c can be directly bonded together while one or more conductive pads 238 (two shown) are directly bonded to the conductive interconnects 228 (and/or a bond pad formed thereon) at the back surface. As a result of the hybrid bonds at the first and second interfaces 240a, 240b, the package 200 can have a generally continuous substrate 201 that has a first side 202 and a second side 203.

Further, the conductive features in each of the first, second, and third semiconductor dies 230, 220, 210 can establish various signal routing lines within the package 200. For example, as discussed above, the active cells 212 can be coupled to the CMOS circuitry 222 and/or the interconnect portion 226 at the first interface 240a. The direct connection between the active cells 212 and the CMOS circuitry 222 can increase the speed of the package 200 (e.g., as compared to the device 100 of FIG. 1, by reducing signal travel time between components) and/or reduce the number of signal routing lines necessary to maintain synchronization of components therein (e.g., corresponding components can be vertically aligned). However, the first semiconductor die 230 can provide signal routing lines (e.g., trace matching features, travel paths, and the like) as necessary. For example, the first semiconductor die 230 can include one or more metallization layers 232 (three illustrated in FIG. 2, referred to individually as “first-third metallization layers 232a-232c”) that are interconnected by redistribution structures 234 (shown schematically) formed therebetween. The first metallization layer 232a can be electrically coupled to the interconnect portion 226, and therefore the active cells 212 through the conductive pads 238. The metallization layers 232 can include any suitable number of signal routing lines for the active cells 212 and/or the CMOS circuitry 222. In this manner, the first, second, and third semiconductor dies 230, 220, 210, in combination, can act as a fully functional, singular semiconductor device.

In some embodiments, the first semiconductor die 230 provides a majority (or all) of the signal route connections for the package 200. That is, signals between various components of the active cells 212 and the CMOS circuitry 222 can be routed through the interconnect portion 226 and the metallization layers 232 to move between circuits. In such embodiments, the BEOL structures in the first semiconductor die 230 can allow the third and second semiconductor dies 210, 220 to each contain fewer metal routing layers. In a specific, non-limiting example, each of the third and second semiconductor dies 210, 220 can contain only two, or only one, layers of copper routing lines. The reduction in routing lines in the third and second semiconductor dies 210, 220 can simplify the manufacturing processes for these semiconductor dies, in turn reducing the number of errors in manufacturing, reduce costs, and/or otherwise increase throughput. Meanwhile, because the first semiconductor die 230 does not contain active cells and/CMOS circuitry, it can be relatively easy and/or cheap to include additional metallization layers (e.g., compared to including the layers on the third and second semiconductor dies 210, 220.

Additionally, or alternatively, the conductive features in each of the first, second, and third semiconductor dies 230, 220, 210 can establish various signal routing lines between the first side 202 and the second side 203. For example, as further illustrated in FIG. 2, the back side of the third semiconductor die 210 can include one or more second bonds pads 216b (four shown) that are electrically coupled to one or more of the active cells 212 and/or the first bond pads 216a by redistribution structures 218 (e.g., conductive vias, shown schematically). Similarly, the third metallization layer 232c can include (or be electrically coupled to) one or more third bond pads 236 at an outer surface of the first semiconductor die 230 (e.g., the first side 202 of the package 200). As a result, electrical signals arriving at the first side 202 (or the second side 203) can be communicated to a corresponding component (e.g., to one of the active cells 212 for processing in conjunction with the CMOS circuitry 222). Additionally, or alternatively, the signals can be communicated through the package 200 to another device (e.g., between the first side 202 and the second side 203), thereby allowing multiple devices to be stacked on top of each other.

The modular construction of the package 200 allows each of the first, second, and third semiconductor dies 230, 220, 210 to be manufactured in bulk processes specific to the components of the package 200 carried thereon before being conjoined to form the package 200. For example, the third semiconductor die 210 can be manufactured in wafer-level processes that are specific to forming the active cells; the second semiconductor die 220 can be manufactured in wafer-level processes that are specific to forming the CMOS circuitry; and the first semiconductor die 230 can be manufactured in wafer-level processes that are specific to forming the BEOL structures in the metallization layers 232. The first, second, and third semiconductor dies 230, 220, 210 can then be singulated from their respective wafers, stacked, and bonded together to form the package 200. In some embodiments, the first, second, and third semiconductor dies 230, 220, 210 are stacked and bonded at the wafer level, before singulation separates individual devices.

As a result of the wafer-level manufacturing of the first, second, and third semiconductor dies 230, 220, 210 can each have an independent thickness. For example, the base substrate 204a of the third semiconductor die 210 can have a first thickness Tₐ; the base substrate 204b of the second semiconductor die 220 can have a second thickness T_{b} that is independent from the first thickness Tₐ; and the base substrate 204c of the first semiconductor die 230 can have a third thickness T_{c} that is independent from the first and second thicknesses Tₐ, T_{b}. In the illustrated embodiment, for example, the base substrate 204a of the third semiconductor die 210 has been polished such that the first thickness Tₐ is less than the second and third thicknesses T_{b}, T_{c}. The polishing can reduce an overall thickness T of the package 200 and/or allow the redistribution structures 218 to more easily be formed. The reduction, however, may only be possible due to the structural support the active cells 212 receive from the base substrates 212b, 212c in the second and first dies 220, 230. Similarly, the base substrate 204b of the second semiconductor die 220 can be polished to reduce the second thickness T_{b} (and therefore the overall thickness T) based on the structural support the CMOS circuitry 222 receives from the base substrates 212a, 212c in the third and first dies 210, 230.

Further, the individual, wafer-level manufacturing of the first, second, and third semiconductor dies 230, 220, 210 can help accelerate the manufacturing process. For example, the individual, wafer-level manufacturing allows each of the first, second, and third semiconductor dies 230, 220, 210 to be manufactured simultaneously, rather than sequentially. Additionally, or alternatively, the individual, wafer-level manufacturing can help reduce costs during manufacturing. For example, the individual, wafer-level manufacturing does not require any protective layers to be formed over the active cells during CMOS manufacturing.

In a specific, non-limiting example, the separate wafer-level manufacturing process can allow the first and/or second semiconductor dies 230, 220 to be manufactured in bulk without customization for the specific application of the resulting package (e.g., forming the same array cells 212 and CMOS circuitry 222 for each die, even when intended for different applications). The first semiconductor die 230 can then couple different components of the first and second semiconductor dies 230, 220 together for different device configurations (e.g., thereby forming different circuits, utilizing different optional components in the circuits, and the like). By relying on the BEOL structures in the first semiconductor die 230 to customize the device for different configurations, the first and/or second semiconductor dies 230, 220 can be manufactured in even greater bulk, thereby realizing various efficiencies of scale.

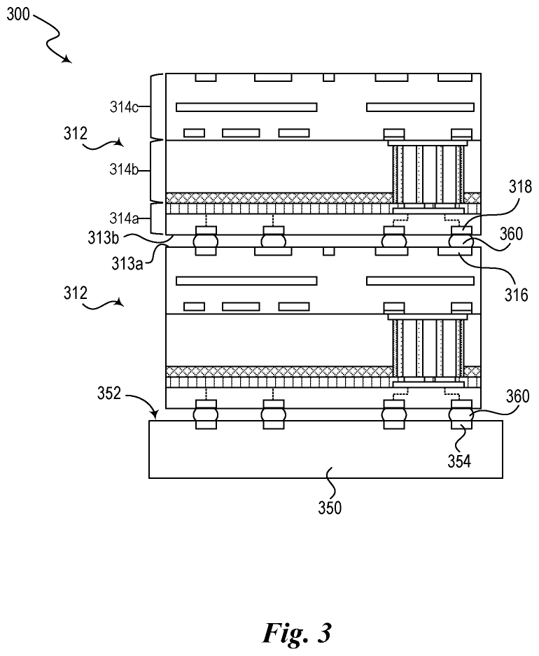

FIG. 3 is a partially schematic cross-sectional view of a semiconductor device 300 configured in accordance with further embodiments of the present technology. The semiconductor device 300 takes advantage of the electrical connection between the first side 202 and the second side 203 of the package 200 discussed with reference to FIG. 2 to create a die stack 310 on a support substrate 350. The die stack 310 can include two or more die semiconductor packages 312 (“packages 312,” two shown), each of which is generally similar to the package 200 of FIG. 2. For example, as illustrated in FIG. 3, each of the packages 312 includes first-third semiconductor dies 314a-c hybrid bonded together. Further, each of the packages includes first bond pads 316 on a first surface 313a and second bond pads 318 on a second surface 313b. The conductive features of each of the packages 312 (e.g., redistribution structures, interconnects, metallization layers, and the like) can electrically couple the first bond pads 316 to the second bond pads 318. The connections allow the packages 312 in the die stack 310 to be interconnected and allow the die stack 310 to be electrically coupled to the support substrate 350.

For example, as further illustrated in FIG. 3, the semiconductor device 300 can further include conductive structures 360 (e.g., a solder ball, solder pillar, conductive pillar, and the like) electrically coupling corresponding pairs of the first and second bond pads 316, 318. Similar, the conductive structures 360 can electrically couple the second bond pads 318 of a lowermost one of the packages 312 to package bond pads 354 on a support surface 352 (e.g., an active and/or upper surface) of the support substrate 350. As a result, signals arriving at the support substrate 350 can be routed to an appropriate destination (e.g., to any group, or all, of the packages 312). Additionally, or alternatively, signals generated in any of the packages 312 can be routed through the support substrate 350 to any appropriate destination.

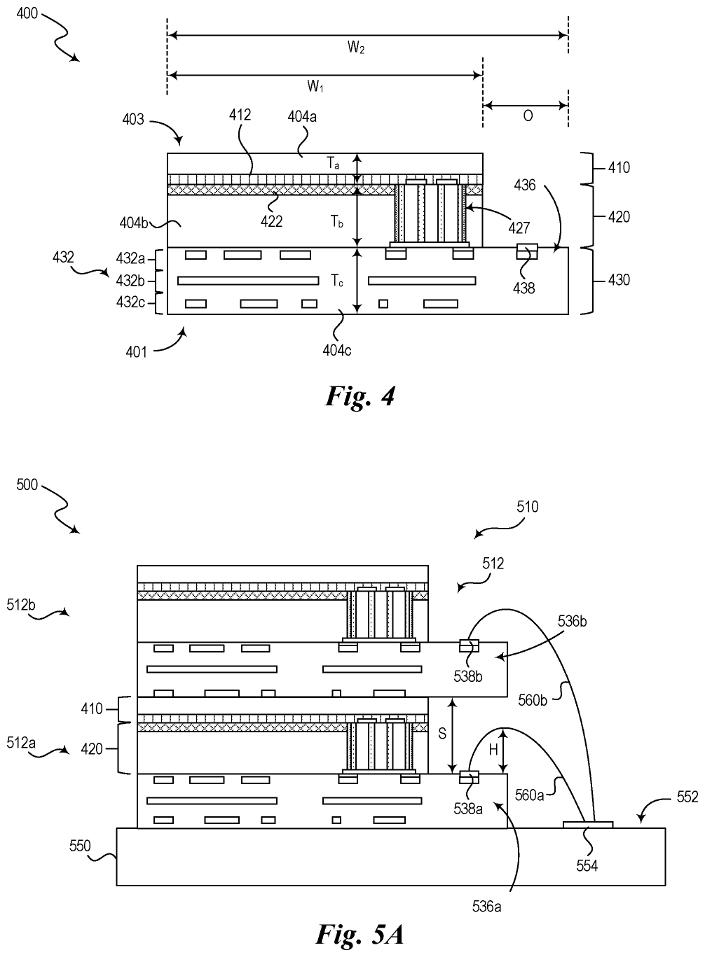

FIG. 4 is a partially schematic cross-sectional view of a semiconductor die package 400 configured in accordance with further embodiments of the present technology. As illustrated in FIG. 4, the semiconductor die package (“package 400”) is generally similar to the package 200 discussed above with reference to FIG. 2. For example, the package 400 includes third semiconductor die 410, a second semiconductor die 420, and first semiconductor die 430. The third semiconductor die 410 includes a first base substrate 402a and an array of active cells 412 formed on the first base substrate 402a; the second semiconductor die 420 includes a second base substrate 402b and CMOS circuitry 422 (and/or other peripheral circuitry) formed on the second base substrate 402b; and the first semiconductor die 430 includes a third base substrate 402c and a plurality of metallization layers 432 formed in the third base substrate 402c. Furthermore, the first semiconductor die 430 can be coupled to the third semiconductor die 410 through an interconnect portion 427 of the second semiconductor die 420.

In the illustrated embodiment, however, the vertical position of the first, second, and third semiconductor dies 430, 420, 410 has been flipped such that the second semiconductor die 420 is carried by the first semiconductor die 430 and the third semiconductor die 410 is carried by the second semiconductor die 420. Furthermore, each of the first and second semiconductor dies 410, 420 have a first width W₁ while the first semiconductor die 430 has a second width W₂ that is greater than the first width W₁. The difference between the first width W₁ and the second width W₂ results in a porch 436 of the first semiconductor die 430 being exposed in an open region O.

As further illustrated in FIG. 4, the porch 436 can include one or more bond pads 438 (one shown in the cross-section). As discussed in more detail below, the bond pads 438 can allow the package 400 to be coupled to external components, such as additional packages, a support substrate, and the like. Furthermore, the bond pads 438 can be electrically coupled to various components of the first and second semiconductor dies 410, 420 via the metallization layers 432 and the interconnect portion 427. Accordingly, the bond pads 438 can help establish a signal route from the external components to the active components of the package 400.

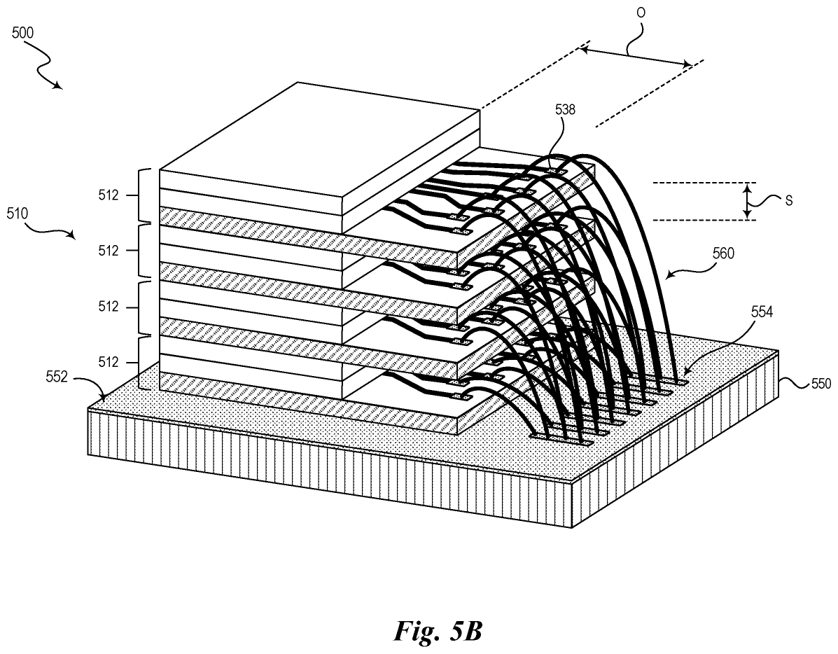

FIG. 5A is a partially schematic cross-sectional view of a semiconductor device 500 configured in accordance with some embodiments of the present technology. In the illustrated embodiment, the semiconductor device 500 (“device 500”) includes a support substrate 550 and a die stack 510 carried by a support surface 552 of the support substrate 550. Further, the die stack 510 includes one or more semiconductor die packages 512 (“packages 512,” two shown, referred to individually as first and second packages 512a, 512b) of the type discussed above with reference to FIG. 4, each of which is electrically coupled to one or more package bond pads 554 (one shown in cross-section) on the support surface 552.

For example, each of one or more bond pads 538a (one shown in cross-section) on the porch 536a of the first package 400a are coupled to a bond wire 560a. In turn, the bond wire 560a is electrically coupled to a corresponding one of the package bond pads 554. Similarly, each of one or more bond pads 538b (one shown in cross-section) on the porch 536b of the second package 400b are coupled to a bond wire 560b. In turn, the bond wire 560b is electrically coupled to a corresponding one of the package bond pads 554. Accordingly, the bond wires 560a, 560b electrically couple the support substrate 550 to each of the packages 400 in the die stack 510.

As further illustrated in FIG. 5A, the combined thickness of the first and second semiconductor dies 410, 420 in the first package 512a results in a space S between the porch 536a of the first package 512a and the porch 536b of the second package 512b. The space S provides the bond wires 560a with room to make a connection to the bond pad 538a on the first package 400a. As long as the space S is greater than a height H of the bond wire 560a, electrical connections to first package 512a (and the semiconductor dies therein) can be made with a wire bonding technique. The wire bonding technique can provide a low-cost alternative to forming conductive vias but can require some additional longitudinal footprint.

FIG. 5B is a partially schematic isometric view of the semiconductor device 500 configured in accordance with some embodiments of the present technology. In the illustrated embodiment, the die stack 510 includes four of the packages 512, each of which includes a plurality of bond pads 538 on a respective porch 536. Similarly, the support surface 552 of the support substrate 550 includes a plurality of package bond pads 554.

As further illustrated in FIG. 5B, the open region O created by the varied widths of the semiconductor dies in each of the packages 512 provides space for the bond pads 538 to be staggered on the porch 536. As a result, a relatively high density of electrical connections can be created between each of the packages and the support substrate 550. For example, as illustrated, the combination of the open region O and the space S provide real estate for a plurality of the bond wires 560 to be formed between each of the bond pads 538 and at least one of the package bond pads 554. Each of the bond wires 560 can then provide an individual signal path to a corresponding one of the packages 400, thereby allowing each of the packages 512 to perform a variety of actions simultaneously.

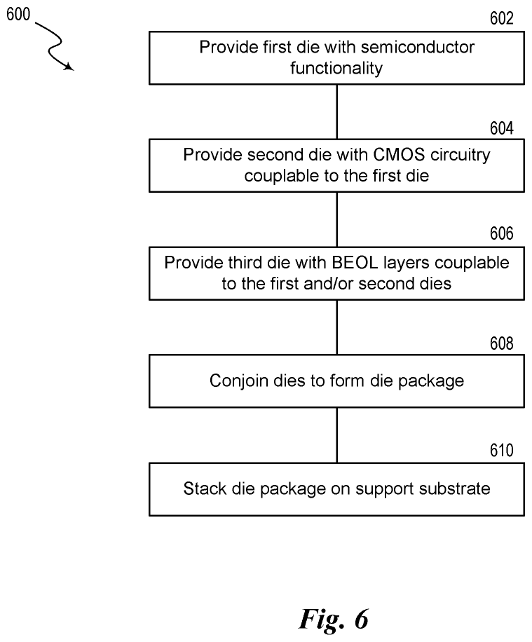

FIG. 6 is a flow diagram of a process 600 for manufacturing a semiconductor die package of the type discussed above with reference to FIGS. 2-5B in accordance with some embodiments of the present technology.

The process 600 begins at block 602 with providing a first die with semiconductor functionality, exclusive of peripheral circuitry associated with the semiconductor functionality (e.g., CMOS circuitry). For example, the first die can include an array of active cells forming a memory die, a CPU die with an arithmetic logic region, a GPU die (e.g., with a graphics and computational array), and the like. In some embodiments, the first die is provided as an individual di (e.g., a singulated die). In some embodiments, the first die is provided in a wafer of similar (or equivalent) first dies.

At block 604, the process 600 includes providing a second die with the peripheral circuitry associated with the first die. Similar to the provision of the first die, the second die can be provided as an individual die (e.g., singulated from a wafer) and/or can be provided in a wafer of similar (or equivalent) second dies each corresponding to a first die in the wafer of first dies.

At block 606 the process 600 includes providing a third die with BEOL structures associated with the components of the first and second dies. For example, the BEOL structures can establish signal routes between components of the first and second dies and/or can establish signal routes to external components. Similar to the provision of the first and second dies, the third die can be provided as an individual die (e.g., singulated from a wafer) and/or can be provided in a wafer of similar (or equivalent) third dies each corresponding to a pair of the first and second dies in corresponding wafers.

In some embodiments, the provision of the first-third dies in blocks 602-606 includes stacking successive dies on previous dies. For example, the second die can be stacked on the first die, then the third die can be stacked on the second die. In some embodiments, blocks 602-606 are executed in an alternative order. For example, the process 600 can execute blocks 602-606 in inverse order to provide the third die, stack the second die on the third die, then the first die on the second die. In some embodiments, the process 600 includes providing additional dies. Purely by way of example, an additional pair of the first and second dies can be stacked over the third die, thereby allowing the BEOL circuitry in the third die to service two groups of FEOL components in a single package.

At block 608, the process 600 includes conjoining each of the provided dies to form a die package. The dies provided in blocks 602-606 can include one or more conductive components of the dies (e.g., bond pads, traces, interconnect surfaces, and the like) and a dielectric material at each surface. Furthermore, at each interface of corresponding dies (e.g., the interface between the first and second dies, the interface between the second and third dies, etc.), the conductive features on each die can be in direct contact with a corresponding conductive feature, and the dielectric material can be in direct contact with a corresponding dielectric layer. In some embodiments, conjoining the dies can include aligning the provided dies to establish the direct contact between corresponding components at each interface and/or polishing the surfaces at each of the interfaces to reduce contaminants. Once the direct contact is established and/or the surfaces are polished, conjoining the provided dies can include forming a hybrid bond at each interface (e.g., forming metal-metal bonds between the conductive features and dielectric-dielectric bonds between the dielectric layers). The hybrid bonding process can include applying heat and/or pressure to the provided dies.

In some embodiments, the conjoining process is done for each package in individual form (e.g., when each of the dies is provided after singulation). The individual treatment can help confirm alignment between the corresponding components at each of the interfaces (e.g., with relatively few components to align. In some embodiments, the conjoining process is completed at a wafer level. The wafer level conjoining process can reduce manufacturing costs and time during manufacturing by completing the conjoining in bulk.

At block 610, the process includes stacking one or more completed packages on a support substrate. In some embodiments (e.g., as discussed above with respect to FIG. 3), stacking the packages includes forming flip chip connections to the support substrate. In some embodiments (e.g., as discussed above with respect to FIGS. 5A and 5B), stacking the packages includes forming bond wire connections to the support substrate. In some embodiments having multiple packages, each of the packages is stacked before forming the connections to the support substrate. For example, each of the packages can be attached in a die stack, then the bond wires can be formed for each package in the die stack. In some having multiple packages, the packages are stacked and electrically coupled to the support substrate on an individual basis.

The conjoining process and/or the stacking process can include a removal process to expose portions of any of the dies in the package. For example, in embodiments where the third die (e.g., having the BEOL structures) has a larger longitudinal footprint than the remaining dies (e.g., resulting in the porch discussed above with reference to FIGS. 4-5B), the first and second dies (and/or any other dies) can include an excess portion to aid in aligning the dies while stacking. Once stacked, the process 600 can then include removing the excess portions to expose the porch. The removal process can also be applied in wafer level stacking processes, where excess is included in the wafer to ensure alignment of the individual packages when the wafers are stacked.

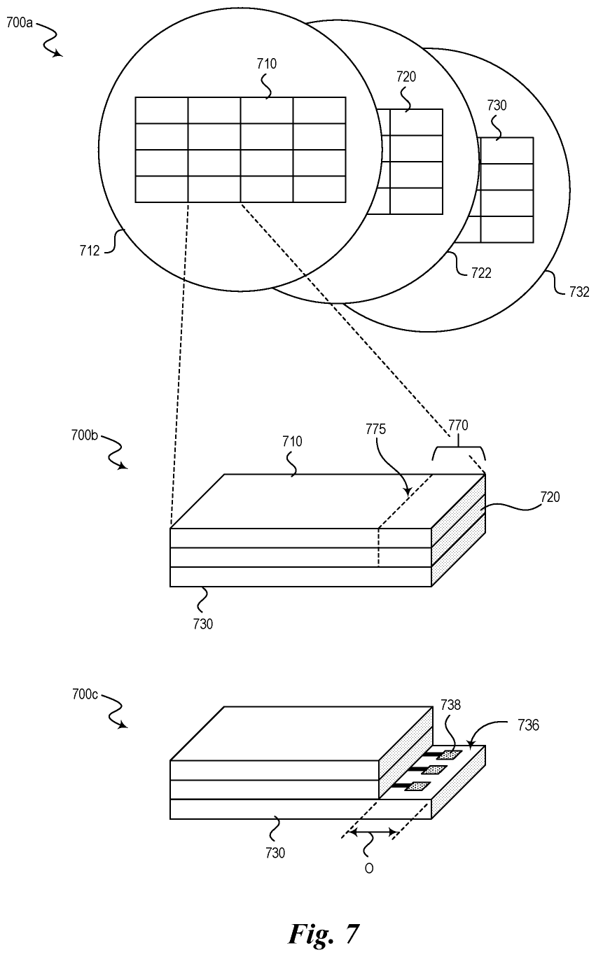

FIG. 7 includes schematic diagrams 700a-c illustrating a semiconductor die package after various steps of the process 600 of FIG. 6 in accordance with embodiments of the present technology. Diagram 700a shows a third semiconductor wafer 712 including a plurality of third dies 710, a second semiconductor wafer 722 including a plurality of second dies 720, and a first semiconductor wafer 732 including a plurality of first dies 730. Each of the third dies 710 can include an array of active cells (e.g., array of memory cells, an array of CPU cells, and the like), exclusive of circuitry configured to access the active cells. Each of the second dies 720 can have the same area as each of the third dies 710 and include corresponding peripheral circuitry (e.g., CMOS circuitry) for the active cells. Each of the first dies 730 can have the same area as each of the third and second dies 710, 720 and include the corresponding BEOL circuitry associated with the active cells and peripheral circuitry on the on the third and second dies 710, 720.

The third, second, and first semiconductor wafers 712, 722, 732 can then be stacked and conjoined to form semiconductor packages. As discussed above, the stacking process can include aligning corresponding conductive components and/or dielectric layers at each interface (e.g., between the third dies 710 and the second dies 720, and between the second dies 720 and the first dies 730). Once stacked, the third, second, and first semiconductor wafers 712, 722, 732 can be conjoined through a hybrid bonding process to form a plurality of packages in a conjoined wafer. The plurality of packages can then be singulated to isolate individual packages 701, as shown in the diagram 700b.

As further illustrated in the diagram 700b, the third and second dies 710, 720 can include a segment 770 (or a portion) of excess semiconductor substrate. The segment 770 can include a sacrificial amount of semiconductor substrate. For example, the segment 770 can allow the third, second, and first dies 710, 720, 730 to have an equal area during the stacking and conjoining process, then can be removed to expose the porch 736 of the first die 730, as illustrated in the diagram 700c. The removal of the segment 770 can also expose a one or more bond pads 738 (e.g., the bond pads 438 of FIG. 4) on the porch 736.

In some embodiments, removing the segment 770 includes severing the segment 770 from the third and second dies 710, 720 using a dicing process (e.g., separating the segment 770 from the third and second dies 710, 720 by dicing through a border 775 between the third and second dies 710, 720 and the segment 770). In some embodiments, the segment 770 is removed in conjunction with other dicing processes, such as while singulating the packages 701. In some embodiments, removing the segment 770 includes severing the segment 770 using an etching process. For example, a photolithography process can cover the third die 710 with a photoresist while exposing a section of the third die 710 corresponding to the segment 770. Subsequently, the etch process can remove the exposed portions from the third and second dies 710, 720. In another example, a photolithography process can expose sections of the third semiconductor wafer 712 after the wafers are stacked and/or conjoined. Subsequently, the etch process can separate the segment 770 from each of the third and second dies 710, 720 on the first and second semiconductor wafers 712, 712 by creating a trench, where a width of the trench includes the border 775 and a depth of the trench approximately corresponds to a thickness of the first and second wafers 712, 722. Thereafter, a cleaning process can be used to remove the separated segment 770 and the third, second, and first wafers 712, 722, 732, can be diced to singulate the packages 701. In some embodiments, the third, second, and first semiconductor wafers 712, 722, 732 are each singulated before stacking and conjoining the third, second, and first dies 710, 720, 730. In such embodiments, the segment 770 can be removed from each of the third and second dies 710, 720 before stacking and conjoining the dies.

In some embodiments, the stacking and conjoining process do not remove the segment from the third and second dies 710, 720. For example, in some embodiments, the first die 730 does not include the porch 736. For example, as discussed above, the packages 701 can include bond pads on the upper and lower surfaces that allow the packages 701 to be interconnected (e.g., as discussed above with respect to FIG. 3).

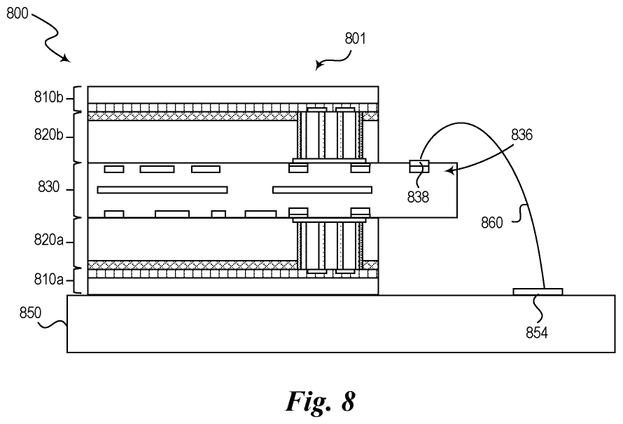

FIG. 8 is a partially schematic cross-sectional view of a semiconductor device 800 configured in accordance with further embodiments of the present technology. As illustrated in FIG. 8, the semiconductor device (“device 800”) is generally similar to the device 500 discussed above with reference to FIG. 5A. For example, the device 800 includes a support substrate 850 and a semiconductor die package 801 (“package 801”) carried by a support surface 852 of the support substrate 850. The package 801 includes a third semiconductor die 810a, a second semiconductor die 810b, and first semiconductor die 830. The third semiconductor die 810a includes an array of active cells coupled directly to CMOS circuitry (and/or other peripheral circuitry) formed on the second die 820a and coupled to the third die 930 through the second die 820a. Furthermore, the first semiconductor die 830 includes a porch 836 that has one or more bond pads 838 that are coupled to a one or more package bond pads 854 on the support substrate 850.

However, in the illustrated embodiment, the first and second semiconductor dies 810a, 820a are a first pair of FEOL dies coupled to the third die 830 and the package 801 further includes a second part of FEOL dies coupled to the first semiconductor die 830. More specifically, the package 801 includes a fourth semiconductor die 810b that includes an array of active cells and a fifth semiconductor die 820b that includes CMOS circuitry directly coupled to the array of active cells. The fifth semiconductor die 820b is carried by (and coupled to) the third semiconductor die. The fourth semiconductor die 810b is carried by the fifth semiconductor die 820b and electrically coupled to the first semiconductor die 830 through the second semiconductor die 820b.

Accordingly, the package 801 effectively functions as a single device with at least two pairs of FEOL dies providing semiconductor functionality. In some embodiments, each of the pairs of FEOL dies provides the same functionality (e.g., providing memory dies, logic dies, CPU dies, and the like). In other embodiments, each of the pairs of FEOL dies can have an independent functionality (e.g., the first pair can provide cache memory while the second pair provides logic processing). In such embodiments, the first semiconductor die 830 can provide electrical connections between the different functionality (e.g., providing the logic dies with direct access to the memory dies). Furthermore, the first semiconductor die 830 can electrically couple both of the pairs of FEOL dies to the support substrate 850, thereby providing a connection to external components (e.g., an external control circuit).

In some embodiments, the package 801 can include additional semiconductor dies with additional semiconductor components. For example, the package can include an additional die with BEOL functionality, additional FEOL dies, and the like. Additionally, or alternatively, similar to the die stacks discussed above, the device 800 can include one or more additional packages stacked on the package 801. Still further, although illustrated as connected through the porch 836 on the first semiconductor die 830, it will be understood that each of the semiconductor dies in the package 801 can have a generally equal longitudinal footprint and can instead be coupled by one or more interconnects, redistribution structures, and the like.

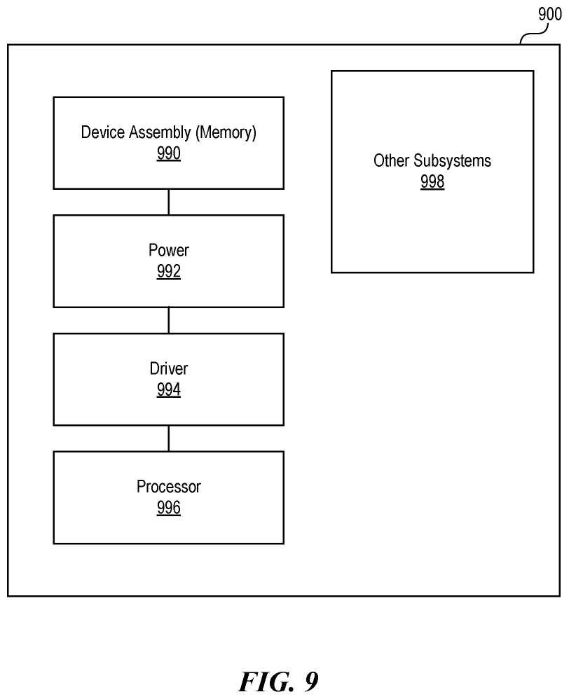

FIG. 9 is a schematic view of a system that includes a semiconductor die assembly configured in accordance with embodiments of the present technology. The semiconductor device assemblies discussed above, can be incorporated into any of a myriad of larger and/or more complex systems, a representative example of which is system 900 shown schematically in FIG. 9. The system 900 can include a memory 990 (e.g., SRAM, DRAM, flash, and/or other memory devices), a power supply 992, a drive 994, a processor 996, and/or other subsystems or components 998. Semiconductor devices having packages on bonded dies (e.g., of the type discussed above with respect to FIG. 2) can be included in any of the elements shown in FIG. 9. Purely by way of example, the memory 990 can include a semiconductor device with packages of direct-bonded dies coupled to a support substrate to improve the speed of and/or reduce the size of the memory 990.

The resulting system 900 can be configured to perform any of a wide variety of suitable computing, processing, storage, sensing, imaging, and/or other functions. Accordingly, representative examples of the system 900 include, without limitation, computers and/or other data processors, such as desktop computers, laptop computers, Internet appliances, hand-held devices (e.g., palm-top computers, wearable computers, cellular or mobile phones, personal digital assistants, music players, etc.), tablets, multi-processor systems, processor-based or programmable consumer electronics, network computers, and minicomputers. Additional representative examples of the system 900 include lights, cameras, vehicles, etc. With regard to these and other examples, the system 900 can be housed in a single unit or distributed over multiple interconnected units, e.g., through a communication network. The components of the system 900 can accordingly include local and/or remote memory storage devices and any of a wide variety of suitable computer-readable media.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10 percent of a given value or limit. Purely by way of example, an approximate ratio means within ten percent of the given ratio.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A semiconductor die package, comprising:
a first semiconductor die comprising:
a first semiconductor substrate having an inner surface and an outer surface opposite the inner surface; and
a plurality of metallization layers formed in the first semiconductor substrate;
a second semiconductor die comprising:
a second semiconductor substrate having a front surface and a back surface opposite the front surface, wherein the back surface is hybrid bonded to the inner surface of the first semiconductor substrate;
complementary metal-oxide-semiconductor (CMOS) circuitry formed in the second semiconductor substrate at the front surface; and
an interconnect section electrically coupling the back surface to the front surface; and
a third semiconductor die comprising a third semiconductor substrate having an array of active cells formed therein, wherein:
the third semiconductor substrate includes a front side and a back side opposite the front side, and
the front side includes conductive components, and wherein the front side is hybrid bonded to the front surface of the second semiconductor substrate to (1) provide the CMOS circuitry with access to the active cells and (2) electrically couple the active cells to the plurality of metallization layers through the interconnect section.

2. The semiconductor die package of claim 1 wherein the plurality of metallization layers form at least one signal route line between a first component in the CMOS circuitry and a second component in the active cells.

3. The semiconductor die package of claim 1 wherein the first semiconductor substrate has a first thickness, the second semiconductor substrate has a second thickness different than the first thickness, and the third semiconductor substrate has a third thickness different than the first thickness and the second thickness.

4. The semiconductor die package of claim 1 wherein the first semiconductor die includes a porch extending beyond a longitudinal footprint of the second semiconductor die and the third semiconductor die such that a portion of the inner surface of the first semiconductor substrate is exposed, and wherein the exposed portion includes one or more bond pads.

5. The semiconductor die package of claim 4 wherein the second semiconductor substrate and the third semiconductor substrate have a combined thickness that is greater than a height to which bond wires attached to the one or more bond pads rise above the inner surface of the first semiconductor substrate.

6. The semiconductor die package of claim 4, further comprising:
a support substrate, to which the outer surface of the first semiconductor substrate is attached, the support substrate including one or more substrate bond pads; and
one or more bond wires each coupling one of the one or more bond pads on the first semiconductor substrate with a corresponding one of the substrate bond pads.

7. The semiconductor die package of claim 1 wherein each of the first semiconductor die, the second semiconductor die, and the third semiconductor die have a generally equal longitudinal footprint.

8. The semiconductor die package of claim 1 wherein outer surface of the first semiconductor substrate includes one or more first bond pads, wherein the back side of the third semiconductor substrate includes one or more second bond pads individually aligned with a corresponding one of the one or more first bond pads, and wherein the third semiconductor die further comprises at least one interconnect electrically coupling the front side of the third semiconductor substrate to the back side.

9. The semiconductor die package of claim 1 wherein the plurality of metallization layers include conductive components at the outer surface of the first semiconductor substrate, and wherein the semiconductor die package further comprises:
a fourth semiconductor die comprising:
a fourth semiconductor substrate having a front surface and a back surface opposite the front surface of the fourth semiconductor substrate, wherein the back surface is hybrid bonded to the outer surface of the first semiconductor substrate;
additional CMOS circuitry formed in the fourth semiconductor substrate at the front surface of the fourth semiconductor substrate; and
an interconnect section electrically coupling the back surface of the fourth semiconductor to the front surface of the fourth semiconductor die; and
a fifth semiconductor die comprising a fifth semiconductor substrate having an array of additional active cells formed therein, wherein:
the fifth semiconductor substrate includes a front side and a back side opposite the front side of the fifth semiconductor substrate, and
the front side of the fifth semiconductor substrate is hybrid bonded to the front surface of the fourth semiconductor substrate to (1) provide the additional CMOS circuitry with access to the additional active cells and (2) electrically couple the active cells to the plurality of metallization layers through the interconnect section of the fourth die.

10. A semiconductor die assembly, comprising:
a support substrate;
a first die package carried by the support substrate, the first die package comprising a first die having an inner surface and an outer surface, a second die having a back surface hybrid bonded to the inner surface of the first die and a front surface opposite the back surface, and a third die having a front side hybrid bonded to the front surface of the second die and a back side opposite the front side, wherein the first die is coupled to the third die via an interconnect portion of the second die, and wherein the first die package is electrically coupled to at least one first substrate bond pad on the support substrate; and
a second die package carried by the first die package, the second die package comprising a fourth die having an inner surface and an outer surface, a fifth die having a back surface hybrid bonded to the inner surface of the fourth die and a front surface opposite the back surface, and a sixth die having a front side hybrid bonded to the front surface of the fifth die and a back side opposite the front side, wherein the sixth die is coupled to the fourth die via an interconnect portion of the fifth die, and wherein the second die package is electrically coupled to at least one second substrate bond pad on the support substrate.

11. The semiconductor die assembly of claim 10 wherein the first die has a first thickness, the second die has a second thickness different than the first thickness, and the third die has a third thickness different than the first thickness and the second thickness.

12. The semiconductor die assembly of claim 10 wherein:
the first die has an exposed portion extending beyond a footprint of the second die and the third die wherein the exposed portion of the first die includes a first bond pad;
the fourth die has an exposed portion that extends beyond a footprint of the fifth die and the sixth die, wherein the exposed portion of the fourth die includes a second bond pad; and
the semiconductor die assembly further comprises:
a first bond wire electrically coupling the first bond pad to the at least one first substrate bond pad; and
a second bond wire electrically coupling the second bond pad to the at least one second substrate bond pad.

13. The semiconductor die assembly of claim 12 wherein the second die and the third die have a combined thickness that is greater than a height to which the first bond wire rises off the first bond pad.

14. The semiconductor die assembly of claim 10 wherein:
the first die package further comprises a plurality of first bond pads on the outer surface of the first die and a plurality of second bond pads on the back surface of the third die, wherein each of the plurality of first bond pads is vertically aligned with a corresponding one of the plurality of second bond pads; and
the second die package further comprises a plurality of third bond pads on the outer surface of the fourth die and a plurality of fourth bond pads on the back surface of the sixth die, wherein each of the plurality of third bond pads is vertically aligned with a corresponding one of the plurality of fourth bond pads and a corresponding one of the plurality of second bond pads.

15. The semiconductor die assembly of claim 14 wherein each of the plurality of first bond pads is electrically coupled to a corresponding substrate bond pad on the support substrate via a solder structure, and wherein each of the plurality of third bond pads is electrically coupled to the corresponding one of the plurality of second bond pads via a solder structure.

16. The semiconductor die assembly of claim 10 wherein:
the front surface of the second die and the front side of the third die each includes a plurality of conductive components, wherein individual ones of the plurality of conductive components of the second die are conjoined with corresponding individual ones of the plurality of conductive components of the third die; and
peripheral circuitry of the second die is configured to access an array of active cells of the third die through one or more conjoined conductive components of the plurality.

17. A method of forming a semiconductor assembly, comprising:
providing a first die having an inner surface and an outer surface, the first die comprising a plurality of metallization layers in a first semiconductor substrate;
providing a second die having a front surface and a back surface, the second die comprising complementary metal-oxide-semiconductor (CMOS) circuitry formed in a second semiconductor substrate at the front surface and an interconnect portion extending between the front surface and the back surface;
providing a third semiconductor die having a front side and a back side, the third die comprising an array of active cells formed in a second semiconductor substrate at the front side; and
conjoining the first die, the second die, and the third die together to form a semiconductor package, wherein:
the inner surface of the first die is hybrid bonded to the back surface of the second die, wherein at least one first component of the first die is coupled to the interconnect portion, and
and the front surface of the second die is hybrid bonded to the front side of the third die to provide the CMOS circuitry with access to the active cells, wherein at least one second component of the third die is electrically coupled to the interconnect portion.

18. The method of claim 17 wherein the plurality of metallization layers in the first die form at least one signal route line between the CMOS circuitry in the second die and the active cells in the third die.

19. The method of claim 17, further comprising attaching the semiconductor package to a support substrate having a plurality of substrate bond pads, wherein attaching the semiconductor package includes electrically coupling the third die to at least one of the plurality of substrate bond pads.

20. The method of claim 19, further comprising stacking a second semiconductor package to the semiconductor package, wherein attaching the second semiconductor package includes electrically coupling the second semiconductor package to at least one of the plurality of substrate bond pads.
